(19) United States
(12) Patent Application Publication
(10) Pub. No.: US 2004/0150072 A1
(43) Pub. Date: Aug. 5, 2004

(54) Integrated circuit having an energy-absorbing structure

(76) Inventors: Wolfgang Schnitt, Nordestedt (DE); Johann-Heinrich Fock, Hamburg (DE)

Correspondence Address: Philips Electronics North America Corporation, Intellectual Property & Standards, M/S 41-SJ, 1109 McKay Drive, San Jose, CA, 95131, US

(21) Appl. No.: 10/479,371

(22) PCT Filed: Jun. 3, 2002
(86) PCT No.: PCT/IB02/02011

(30) Foreign Application Priority Data
Jun. 1, 2001 (DE) 101 26 955.2

(51) Int. Cl. H01L 23/58

(52) U.S. Cl. 257/629

(57) ABSTRACT

An integrated circuit whose component body comprises a substrate, circuit elements, interconnection elements, a passivation layer and a fringe segment of a ductile material, wherein the base surface of the component body is formed essentially by the substrate, the cover surface of the component body is formed essentially by the passivation layer and the fringe segment, and the side walls of the component body are formed by the substrate and the fringe segment.

The invention relates to an integrated circuit comprising a substrate, circuit elements, interconnection elements between the circuit elements, a passivation coating and an energy-absorbing structure.

To protect integrated circuits against corrosion and mechanical damage, a passivation coating is provided after the patterning of the uppermost level of metallization for the interconnection elements, which passivation coating is interrupted only at the locations (pads) where the lead wires (bonding wires) are provided.

Mechanical stresses between the layers, insufficient layer adhesion and, in the case of cased integrated circuits, stresses from the compression molding material of the housing may cause cracks in the brittle passivation layer and in the uppermost level of metallization.

To obviate this drawback, U.S. Pat. No. 5,880,528 proposes an integrated circuit having an energy-absorbing structure. This integrated circuit comprises a silicon substrate and a dielectric layer (passivation layer) on the substrate. The integrated circuit further comprises a terminal metallization layer on the dielectric layer. The dielectric layer and the terminal metallization layer form an active area. The integrated circuit further comprises a first guard ring that is formed from the terminal metallization layer. Said first guard ring encloses the active area. The integrated circuit further comprises a second guard ring that is formed from the terminal metallization layer and encloses the first guard ring.

The energy-absorbing structure of the terminal metallization layer, as disclosed in U.S. Pat. No. 5,880,528, cannot preclude, however, the occurrence of shearing forces acting on the open lateral fringes of the passivation layer, which lead to premature failure of the integrated circuit.

Therefore, it is an object of the invention to provide an integrated circuit having an improved energy-absorbing structure.

In accordance with the invention, this object is achieved by an integrated circuit whose component body comprises a substrate, circuit elements, interconnection elements, a passivation layer and a fringe segment of a ductile material, wherein the base surface of the component body is formed essentially by the substrate, the cover surface of the component body is formed essentially by the passivation layer and the fringe segment, and the side walls of the component body are formed by the substrate and the fringe segment.

The low level of resistance of a component body without an energy-absorbing structure to crack propagation is caused by the brittleness of the dielectric layers in the circuit elements and in the passivation coating. The fringe segment of a ductile material is energy-absorbing and capable of reducing any increases in stress by plastic deformation.

By laterally covering the dielectric layers in the circuit elements and covering the passivation layer at the fringes and at the side walls with said ductile fringe segment, breakdown of the integrated circuit caused by crack propagation and brittle fracture of the dielectric layers is precluded.

The ductile material may be selected among the group consisting of the ductile metals, ductile adhesives and ductile polymers.

Preferably, the ductile material has a fracture toughness K_{Ic}≧25 Mpa √m.

In accordance with an embodiment of the invention, the ductile material is selected among the group consisting of the ductile metals aluminum, titanium, gold, silver, nickel and their alloys. If these metals are subject to pressure, they deform plastically and take up the lateral shearing forces.

In accordance with an embodiment of the invention, the fringe segment comprises a metal layer.

Particularly advantageous effects of the invention in relation to the prior art are achieved if the fringe segment comprises two metal layers. Two metal layers can engage, with their inner edges, the layers of the circuit elements and the passivation coating. In this manner forces are absorbed in a particularly favorable manner.

In accordance with a further preferred embodiment, the fringe segment comprises two metal layers and one adhesive layer. This embodiment is particularly suitable for integrated circuits manufactured using SOI technique.

These and other aspects of the invention are apparent from and will be elucidated with reference to the embodiments described hereinafter.

In the drawings:

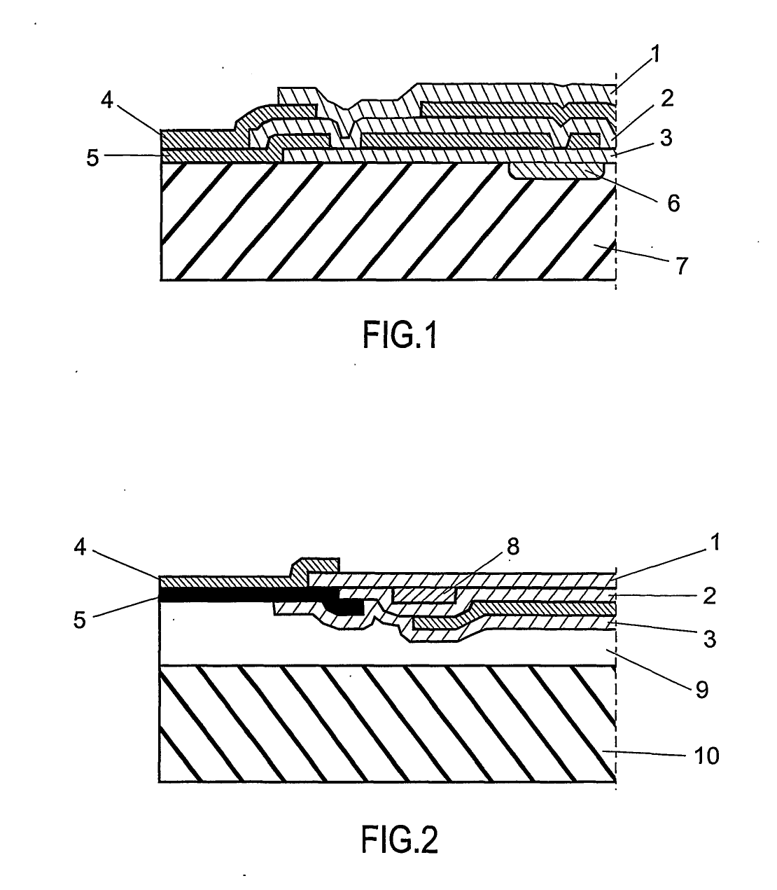

FIG. 1 is a diagrammatic, cross-sectional view of a planar-technology integrated circuit having a fringe segment formed from two metal layers.

FIG. 2 is a diagrammatic, cross-sectional view of a SOI-technology integrated circuit having a fringe segment formed from two metal layers and one adhesive layer.

The integrated circuit in accordance with the invention comprises a semiconductor substrate 7, circuit elements 6, 8 in a silicon dioxide layer 3, interconnection elements 2 between the circuit elements, a passivation coating 1 and an energy-absorbing fringe segment 4, 5 of a ductile material. Such an integrated circuit can be embodied so as to be, for example, a memory circuit, a digital circuit or an analog circuit. The semiconductor substrate may be selected among a plurality of possible substrates, for example semiconductor-grade monocrystalline silicon, semiconductor-grade polycrystalline silicon, semiconductor-grade amorphous silicon, silicon on glass, silicon on sapphire or silicon on quartz. The semiconductor substrate 7 shown in FIG. 1 is a conventional silicon substrate, the semiconductor substrate 10 shown in FIG. 2 is a SOI-substrate of glass on to which the circuit elements are adhered by means of an adhesive layer 9.

The circuit elements of the integrated circuit may comprise all suitable, active and passive components, such as diodes, Schottky diodes, CMOS transistors, bipolar transistors, thin-film transistors, capacitors, resistors, coils, micro and nanocomponents such as IR and UV sensors, gas sensors, optoelectronic components and the associated interconnection elements.

The metal interconnection elements bring the doped regions of the integrated circuit elements into electrical contact with each other and interconnect the individual components of an integrated circuit. Said metal interconnection elements guide the leads as far as the edge of the integrated circuit where they are widened so as to form lands (bonding pads). Customarily, the interconnection elements are arranged in one or more levels of metallization on one or both surfaces of the integrated circuit.

The passivation layer serves as protection against mechanical damage, as protection against corrosion of the metallization for the interconnection elements, as a diffusion barrier and as a gettering layer for impurities, as well as a shield against α radiation. The quality requirements to be met by this passivation layer are in keeping with the above-mentioned applications. Use is predominantly made of silicon oxide and silicon nitride layers. Polymers are used partly as an additional protective layer. As a result of the high internal stresses and the associated risk of crack formation and delamination, the thickness is limited, dependent upon the material used, to approximately 1 μm. The passivation layer is customarily composed of a double layer of plasma oxide and plasma nitride having a thickness of 0.5 to 1 μm each. An additional polyimide layer proved to be very effective. It serves as a stress buffer and provides for excellent adhesion between the compression molding material of the housing and the cover surface of the component body. The passivation layer comprises a contact window through which the contacts of the integrated circuit (pads) are led to the lead wires.

The circuit elements, interconnection elements and the passivation layer are arranged on the substrate in such a manner that a border zone of the substrate remains free of circuit elements, interconnection elements and the passivation coating. On the side of their edges, the circuit elements, connection elements and the passivation layer are surrounded by the fringe segment of a ductile material.

The component body of the integrated circuit (chip) customarily is a cuboid. It is bounded by a base surface, a cover surface and side surfaces.

The base surface of the component body is formed essentially by the substrate, the cover surface of the component body is formed essentially by the passivation layer and the fringe segment, and the side walls of the component body are formed by the substrate and the ductile fringe segment. Consequently, also the edges between the side surfaces and the cover layer are formed by the ductile fringe segment.

The fringe segment of the component body may consist of a laminar structure. Said laminar structure preferably comprises two layers. As shown in FIG. 1 and FIG. 2, the end portions of the layers facing the active part of the integrated circuit preferably engage the laminar structure of the circuit elements and interconnection elements.

The fringe segment may also comprise one layer of a ductile adhesive, particularly if the integrated circuit is manufactured using SOI technique.

The ductile material may be selected among the group consisting of the ductile metals, ductile adhesives and ductile polymers.

Preferably, the ductile material has a fracture toughness K_{Ic}≧25 Mpa √m. The fracture toughness is a measure of the resisting capacity of crack-sensitive materials to fracture causing total breakdown.

The ductile material is preferably selected among the group consisting of the ductile metals aluminum, titanium, gold, silver, nickel and the alloys thereof. If these metals are subject to pressure, they deform plastically and take up lateral shearing forces.

A method of manufacturing an integrated circuit in accordance with a first embodiment of the invention will be described hereinafter.

Initially, the integrated circuit is built up like a component whose integrated circuit elements, for example diodes, transistors, resistors, as well as the connections between the integrated circuit elements are all arranged in or on a common substrate in a manner known to those skilled in the art, and jointly form the component.

To manufacture the circuit elements, processes are carried out at or close to the surface of a monocrystal that is of a defined conductivity type and comprises an exact conductivity area. The circuit elements are selectively incorporated using, for example, planar or SOI technology in combination with a plurality of oxidation steps, photolithography processes, selective etching and intermediate doping steps such as diffusion or ion implantation. SOI-technology integrated circuits are adhered to an insulating substrate by means of an adhesive layer in a manner known to those skilled in the art. An fringe area of the substrate, which area will be covered by the fringe segment at a later stage, is left uncovered or made bare again.

For the interconnection elements made of metals, metal silicides or heavily doped polysilicon, which connect the circuit elements of an integrated circuit with each other and with the contact areas at the edge of the circuit, the entire surface above the circuit is first covered with a metal, metal silicide or heavily doped polysilicon, after which, to provide a pattern, the superfluous areas of the layer are removed by wet chemical or dry etching. Preferably, a first metal layer for the fringe segment is formed together with the uppermost metallization. In accordance with a further embodiment of the invention, two or more metal layers for the fringe segment and interconnection elements for the integrated circuit are jointly formed in a plurality of conductor levels. The outermost fringe area of the substrate remains unmetallized and forms the saw track.

After the metallization process for the interconnection elements, the integrated circuit as such is complete and ready for use. However, as the circuit is susceptible to contamination and the metallization is not scratch-resistant, the integrated circuit is covered with a passivation coating. For said passivation coating use is predominantly made of silicon oxide and silicon nitride layers that are deposited by means of CVD. Said passivation coating is patterned by means of wet-chemical etching or reactive ion etching. In said patterning operation, the contact windows for the bonding pads and the fringe area for the fringe segment are formed. The outermost fringe area of the passivation layer can remain intact to form the saw track.

A further metal layer for the fringe segment can be formed together with the metallizations for the bonding pads.

Subsequently, the integrated circuits are diced along the saw track. Said dicing operation can be carried out by means of, for example, slitting slightly and breaking, laser processing and breaking, sawing or abrasive cutting.

To protect the integrated circuit against mechanical damage and chemical and environmental influences, said integrated circuit is accommodated in a casing that also serves to distribute and discharge the dissipated heat.

In most cases, the component body is coated with a quartz-filled thermoplastic epoxy resin in a compression mold. If special protection against moisture is necessary, or if the integrated circuit should be operated at comparatively high temperatures, use is made of a metal or ceramic casing. The lower part thereof forms a metal or ceramic supporting plate. After bonding, a metal cover is provided to close the housing, which is subsequently soldered up, welded up or glass-sealed. The molding, soldering, welding or glass-sealing operations for encasing the integrated circuit exert a thermal stress and shearing forces on the component body because the metallization layers and the passivation layers have different coefficients of thermal expansion. Similar thermal loads are produced by the heat generated by the component during operation. By embodying the component body's fringe segment in accordance with the invention, it is achieved that the fringe segment deforms plastically when it is subjected to stress, and that lateral shearing forces can no longer cause crack formation and delamination in the component body.

1. An integrated circuit whose component body comprises a substrate, circuit elements, interconnection elements, a passivation layer and an fringe segment of a ductile material, wherein the base surface of the component body is formed essentially by the substrate, the cover surface of the component body is formed essentially by the passivation layer and the fringe segment, and the side walls of the component body are formed by the substrate and the fringe segment.

2. An integrated circuit as claimed in claim 1, characterized in that the ductile material is selected among the group consisting of the ductile metals, ductile adhesives and ductile polymers.

3. An integrated circuit as claimed in claim 1, characterized in that the ductile material has a fracture toughness K_{Ic}≧25 Mpa √m.

4. An integrated circuit as claimed in claim 1, characterized in that the ductile material is selected among the group consisting of the ductile metals aluminum, titanium, gold, silver, nickel and their alloys.

5. An integrated circuit as claimed in claim 1, characterized in that the fringe segment comprises a metal layer.

6. An integrated circuit as claimed in claim 1, characterized in that the fringe segment comprises two metal layers.

7. An integrated circuit as claimed in claim 1, characterized in that the fringe segment comprises two metal layers and one adhesive layer.
